(19) United States
(12) Patent Application Publication
(10) Pub. No.: US 2002/0155709 A1
(43) Pub. Date: Oct. 24, 2002

(54) Method and apparatus of processing surface of substrate

(75) Inventors: Takayuki Toshima, Nirasaki-shi (JP); Miyako Yamasaka, Nirasaki-shi (JP)

Correspondence Address: MORRISON & FOERSTER, LLP, 555 WEST FIFTH STREET, SUITE 3500, LOS ANGELES, CA, 90013-1024, US

(73) Assignee: TOKYO ELECTRON LIMITED

(21) Appl. No.: 10/036,787

(22) Filed: Oct. 19, 2001

(30) Foreign Application Priority Data
Oct. 20, 2000 (JP) 2000-320646

(51) Int. Cl. C23F 1/00; H01L 21/302

(52) U.S. Cl. 438/689; 156/345.11; 156/345.13

(57) ABSTRACT

While supplying DHF as a chemical liquid to wafers W each having a resist pattern formed on the surface, oxidation films on the wafers W are eliminated by etching and successively, the surfaces of the wafers W are cleaned by supplying the wafers W with a rinsing liquid. Subsequently, by supplying an ozone water of a predetermined concentration, oxidation films are formed on the wafers W in order to make their surfaces hydrophilic. Then, N2-gas (dry gas) is supplied to the wafers W in order to remove moisture adhering to the surfaces of the wafers W. In this way, it is possible to prevent an occurrence of water-marks on the wafers W without collapsing the resist patterns formed on the wafers W, allowing both quality and yield rate of the wafers to be improved.

### BACKGROUND OF THE INVENTION

1. Technical Field of the Invention

This invention relates to method and apparatus of processing surfaces of substrates. More in detail, the invention relates to method and apparatus of processing respective surfaces of substrates having resist patterns formed thereon, for example, semiconductor wafers, glass substrates for LCD, etc.

2. Description of the Related Art

Generally, in the manufacturing process for semiconductor devices, there are carried out a series of processes which comprise: applying photo-resist on substrates to be processes, for example, semiconductor wafers, LCD baseplates, etc. (referred “wafers” hereinafter); transferring a circuit pattern, which has been scaled down by the photo-lithography technique, to the above photo-resist; developing this pattern; and thereafter removing the photo-resist from the wafers etc.

In the course of the above processes, after the wafers etc. are etched to remove oxidized films from their surfaces by a chemical liquid, for example, dilute hydrofluoric solution (DHF), the wafers etc. are washed and dried. Due to the water repellent property of the so-etched surfaces of the wafers etc., when the washing and drying processes are applied to the wafers as they are, then water marks are formed on the surfaces of the wafers, causing the yields to be deteriorated.

Therefore, it is conventionally carried out to, after the DHF-etching, dip the wafers etc. into an ozone water to form oxidation films on the surfaces of the wafers while changing their hydrophobic surfaces to hydrophilic surfaces. Subsequently, the wafers are dried by dry solvent, for example, vapor of isopropyl alcohol (IPA) (see Japanese Patent Publication Kokai No. 9-190994). In this way, by changing hydrophobic surfaces to hydrophilic surfaces due to the formation of oxidation films on the wafers etc. and continuously drying them with IPA-vapor, it is possible to restrict the generation of water-marks, allowing a yield rate in production to be improved.

However, when processing wafers etc. having resist patterns formed thereon, there is caused the following problem. That is, the contact of IPA-vapor with the wafers etc. causes the resist to be dissolved by IPA. Consequently, the resist patterns are broken to cause both quality and yield rate of the wafers to be deteriorated. Additionally, if the concentration of ozone in the ozone-water is relatively high, then the resist is dissolved, so that the resist patterns are broken to cause both quality and yield rate of the wafers to be deteriorated, as similar to the above case.

### SUMMARY OF THE INVENTION

Under the above-mentioned circumstances, an object of the present invention is to provide both substrate-surface processing method and apparatus by which an occurrence of water-marks can be prevented without collapsing the resist pattern on a substrate thereby to improve both quality and yield rate of the substrate.

The first feature of the present invention resides in the provision of a method of processing a surface of a substrate to be processed, the method comprising an etching process to supply the substrate having a resist pattern formed thereon with a chemical liquid thereby to remove an oxidation film on the surface of the substrate therefrom, a rinsing process to supply the substrate with a rinsing liquid thereby to wash the surface of the substrate, a hydrophilic process to supply the substrate with an ozone water thereby to form an oxidation film on the surface of the substrate for providing hydrophilicity therefor and a drying process to eliminate water adhering to the surface of the substrate.

Accordingly, after the oxidation film on the surface of the substrate has been removed in etching by supplying the substrate having the resist pattern formed thereon with the chemical liquid, it is carried out to supply the substrate with the rinsing liquid for washing the surface of the substrate and thereafter, the ozone water of a predetermined concentration is supplied to form an oxidation film on the surface of the substrate for its hydrophilicity. Thus, it is possible to prevent an occurrence of water-marks on the surface of the substrate.

The second feature of the present invention resides in that the drying process is accomplished by supplying dry gas to the substrate to be processed. Thus, it is possible to dry the substrate without destroying the resist pattern formed thereon, effectively.

The third feature of the present invention resides in that the drying process is accomplished by rotating the substrate to be processed. Therefore, it is possible to dry the substrate without destroying the resist pattern formed thereon, effectively.

The fourth feature of the present invention resides in that the ozone water in the hydrophilic process has a concentration ranging from 0.5 to 10 PPM. Thus, it is possible to prevent the resist from being dissolved by the ozone water and also possible to provide the substrate with an oxidation film having a film-thickness required to be hydrophilic.

The fifth feature of the present invention resides in the provision of a substrate-surface processing method of sorting out a substrate having a resist pattern formed thereon from another substrate having no resist pattern formed thereon and further applying different processes to the substrates selectively. For the substrate having the resist pattern formed thereon, this method comprises an etching process to supply the substrate with a chemical liquid thereby to remove an oxidation film on the surface of the substrate therefrom, a rinsing process to supply the substrate with a rinsing liquid thereby to wash the surface of the substrate, a hydrophilic process to supply the substrate with an ozone water thereby to form an oxidation film on the surface of the substrate for hydrophilicity thereof and a drying process to eliminate moisture adhering to the surface of the substrate. While, for the substrate having no resist pattern formed thereon, the method comprises an etching process to supply the substrate having no resist pattern formed thereon with a chemical liquid thereby to remove an oxidation film on the surface of the substrate therefrom, a rinsing process to supply the substrate with a rinsing liquid thereby to wash the surface of the substrate and a drying process to supply the substrate with a dry solvent thereby to eliminate moisture adhering to the surface of the substrate.

For the substrate having the resist pattern formed thereon, since the ozone water of a predetermined concentration is supplied to form an oxidation film on the surface of the substrate for its hydrophilicity, it is possible to prevent an occurrence of water-marks on the surface of the substrate. On the other hand, for the substrate having no resist pattern formed thereon, the chemical liquid is supplied to the substrate to remove the oxidation film in etching and the rinsing liquid is successively supplied to wash the surface of the substrate. Thereafter, the dry solvent is supplied to eliminate the moisture adhering to the surface of the substrate. Accordingly, it is possible to prevent an occurrence of water-marks on the surface of the substrate and also possible to dry the substrate effectively. That is, with the completion of the most suitable process corresponding to the presence of resist pattern, it is possible to improve the processing efficiency.

The sixth feature of the present invention resides in that the drying process for the substrate having the resist pattern formed thereon is accomplished by supplying dry gas to the substrate to be processed. Therefore, it is possible to dry the substrate without destroying the resist pattern, effectively.

The seventh feature of the present invention resides in that the drying process for the substrate having the resist pattern formed thereon is accomplished by rotating the substrate to be processed. Therefore, it is possible to dry the substrate without destroying the resist pattern, effectively.

The eighth feature of the present invention resides in the provision of a substrate-surface processing apparatus for processing a surface of a substrate to be processed, the apparatus comprising a processing container for accommodating the substrate therein, a chemical-liquid supply system for supplying the substrate in the processing container with a chemical liquid for removing an oxidation film formed on the substrate, a rinsing-liquid supply system for supplying the substrate in the processing container with a rinsing liquid for washing, an ozone-water supply system for supplying the substrate in the processing container with an ozone water, a substrate drying system for drying the substrate in the processing container, a dry-solvent supply system for supplying the substrate in the processing container with a dry solvent and a controller for generating operative signals to drive both of the ozone-water supply system and the substrate drying system when the substrate having a resist pattern formed thereon is accommodated in the processing container, the controller also generating an operative signal to drive the dry-solvent supply system in place of the ozone-water supply system and the substrate drying system when the substrate having no resist pattern formed thereon is accommodated in the processing container.

That is, the above apparatus includes the controller which generates the operative signals to drive both of the ozone-water supply system and the substrate drying system when the substrate having a resist pattern formed thereon is accommodated in the processing container and which also generates the operative signal to drive the dry-solvent supply system in place of the ozone-water supply system and the substrate drying system when the substrate having no resist pattern formed thereon is accommodated in the processing container. Therefore, for the substrate having the resist pattern formed thereon, since the ozone water of a predetermined concentration is supplied to form an oxidation film on the surface of the substrate for its hydrophilicity, it is possible to prevent an occurrence of water-marks on the surface of the substrate. On the other hand, for the substrate having no resist pattern formed thereon, the chemical liquid is supplied to the substrate to remove the oxidation film in etching and the rinsing liquid is successively supplied to wash the surface of the substrate. Thereafter, the dry solvent is supplied to eliminate the moisture adhering to the surface of the substrate. Accordingly, it is possible to prevent an occurrence of water-marks on the surface of the substrate and also possible to dry the substrate effectively. That is, with the completion of the most suitable process corresponding to the presence of resist pattern, it is possible to improve the processing efficiency.

The ninth feature of the present invention resides in that the substrate drying system is a dry-gas supply system for supplying dry gas into the processing container. Therefore, it is possible to dry the substrate without destroying the resist pattern, effectively.

The tenth feature of the present invention resides in that the rinsing-liquid supply system has a supply pipe which connects a rinsing-liquid source for the rinsing liquid for washing with the processing container, the chemical-liquid supply system has a chemical-liquid source for reserving the chemical liquid for removing the oxidation film and a chemical-liquid pipe connecting the chemical-liquid source with the supply pipe and that the ozone-water supply system has an ozone-water source and an ozone-water pipe connecting the ozone-water source with the supply pipe. Therefore, it is possible to carry out the etching process, the rinsing process and the hydrophilic process effectively.

The 11th. feature of the present invention resides in that the substrate drying system is a rotary drying system which rotates the substrate. Therefore, it is possible to dry the substrate without destroying the resist pattern, effectively.

The 12th. feature of the present invention resides in that the rinsing-liquid supply system has a supply pipe which connects a rinsing-liquid source for the rinsing liquid for washing with the processing container, the chemical-liquid supply system has a chemical-liquid source for reserving the chemical liquid for removing the oxidation film and a chemical-liquid pipe connecting the chemical-liquid source with the supply pipe and that the ozone-water supply system has an ozone-water source and an ozone-water pipe connecting the ozone-water source with the supply pipe. Therefore, it is possible to carry out the etching process, the rinsing process and the hydrophilic process effectively.

The 13th. feature of the present invention resides in that the processing container contains a liquid-process container for carrying out a liquid processing inside thereof and a dry-process container for carrying out a drying process inside thereof.

The 14th. feature of the present invention resides in that the dry-process container is arranged above the liquid-process container and the liquid-process container has a liquid-process chamber connected with a dry-process chamber in the dry-process container through a communication port arranged between the liquid-process container and the dry-process container. With the constitution mentioned above, since it allows the substrate to be moved into the dry-process chamber for the drying process after the etching process, the rinsing process and the hydrophilic process with the ozone water have been applied on the substrate in the liquid-process container, it is possible to apply the etching process, the rinsing process, the hydrophilic process and the drying process on the substrate without being exposed to the air. Therefore, there is no fear of the oxidation film re-adhering to the substrate and additionally, no fear of particles.

The 15th. feature of the present invention resides in that the processing container contains a liquid-process container for carrying out a liquid process inside thereof and a dry-process container for carrying out a drying process inside thereof.

The 16th. feature of the present invention resides in that the liquid-process container is arranged so as to be insertable into and withdrawable from the dry-process container. Further, at the liquid process, the liquid-process container performs the liquid process while accommodating the substrate therein. At the drying processing, the liquid-process container withdraws from a position to accommodate the substrate therein and the dry-process container performs the drying process while accommodating the substrate therein.

### BRIEF DESCRIPTION OF THE DRAWINGS

FIG. 1 is a schematic sectional view showing the first embodiment of a substrate-surface processing apparatus of the present invention;

FIG. 2 is a schematic sectional view showing an etching process of the first embodiment of the invention;

FIG. 3 is a schematic sectional view showing a rinsing process of the first embodiment of the present invention;

FIG. 4 is a schematic sectional view showing a water-intimate (oxidation film deposition) process of the first embodiment of the present invention;

FIG. 5 is a schematic sectional view showing a drying process of the first embodiment;

FIG. 6 is a flow chart showing an order of the processes of the first embodiment of the present invention;

FIG. 7 is a schematic sectional view showing the second embodiment of the substrate-surface processing apparatus of the present invention;

FIG. 8 is a schematic sectional view showing a drying process for wafers having no resist pattern formed thereon in the second embodiment of the invention;

FIG. 9 is a flow chart showing an order of the processes of the second embodiment of the present invention;

FIG. 10A is a schematic sectional view showing the third embodiment of the substrate-surface processing apparatus of the present invention;

FIG. 10B is a view showing a condition to move an inner cylinder back to a stand-by position in FIG. 10A;

FIG. 11 is a flow chart showing an order of the processes of the third embodiment of the present invention;

FIG. 12 is a schematic plan view showing a processing system on which the substrate-surface processing apparatus of the present invention is applied;

FIG. 13 is a graph showing a relationship between a film-thickness of oxidation film and a rinsing period of ozone water; and

FIG. 14 is a graph showing a relationship between a concentration of ozone water and a rise time thereof.

### DESCRIPTION OF THE PREFERRED EMBODIMENT

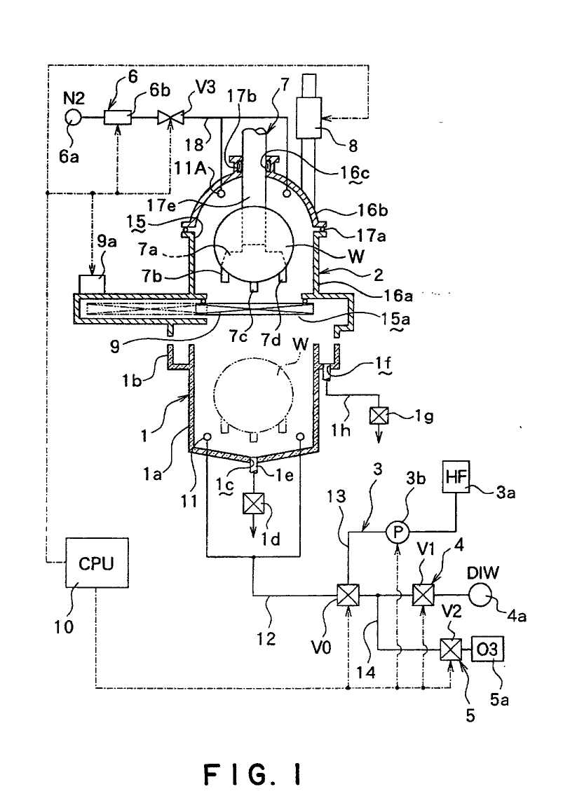

With reference to FIGS. 1 to 14, embodiments of the present invention will be described below. Hereat, we describe the application of a substrate-surface processing apparatus of the invention to a processing apparatus for etching, cleaning and drying semiconductor wafers (referred “wafers” hereinafter) having resist-patterns formed thereon.

1st. Embodiment

FIG. 1 is a schematic sectional view showing the first embodiment of the substrate-surface processing apparatus of the present invention.

The above processing apparatus includes a processing bath 1 as a processing chamber to accommodate the wafers W therein, a drying chamber 2 to accommodate the wafers W positioned above the processing bath 1, a chemical-liquid supplier 3 for supplying the wafers W in the processing bath 1 with a chemical liquid for removing an oxidation film, for example, dilute hydrofluoric solution (DHF), a rinsing-liquid supplier 4 for supplying the wafers W in the processing bath 1 with a rinsing liquid for cleaning the wafers W, an ozone-water supplier 5 for supplying the wafers W in the processing bath 1 with an ozone water, a dry-gas supplier 6 for supplying the drying chamber 2 with a dry gas, for example, nitrogen gas (N₂-gas), fresh air, etc. and a controller, for example, a central processing unit 10 (referred “CPU 10” hereinafter) for transmitting control (operational) signals to the chemical-liquid supplier 3, the rinsing-liquid supplier 4, the ozone-water supplier 5, the dry-gas supplier 6, a wafer guide 7 mentioned later, a container-cover elevating mechanism 8, a shutter 9 and so on.

In this case, the processing bath 1 is formed by an inner bath 1a for accommodating the wafers W and an outer bath 1b surrounding the periphery of a top opening of the inner bath 1a. The inner bath 1a is provided, on a bottom thereof, with a drain port 1c to which a drain pipe 1e including a drain valve 1d is connected. The outer bath 1b is provided, on a bottom thereof, with a drainage port 1f to which a drainage pipe 1h including a closing valve 1g is connected.

Supply nozzles 11 are arranged on an underside in the inner bath 1a of the processing bath 1. The supply nozzles 11 are connected to a source 4a for pure water (DIW) as a rinsing liquid through a main supply pipe 12. On the side of the pure-water source 4a, the main supply pipe 12 interposes a first closing valve V1. The rinsing-liquid supplier 4 is formed by the pure-water source 4a, the main supply pipe 12, the first closing valve V1 and the supply nozzles 11.

The main supply pipe 12 further interposes a switching valve V0 which is connected to a supply tank 3a for a chemical liquid, for example, hydrous fluoride (HF) through a chemical supply pipe 13. Note, the chemical-liquid supply pipe 13 interposes a pump 3b therein. The chemical-liquid supplier 3 is formed by the supply tank 3a, the chemical supply pipe 13, the pump 3b, the switching valve V0, the main supply pipe 12 and the supply nozzles 11. In this arrangement, the pure water flowing through the main supply pipe 12 and the hydrous fluoride (HF) supplied from the supply tank 3a are mixed together to supply a chemical liquid (DHF) of constant concentration into the processing bath 1 through the supply nozzles 11.

Between the first valve V1 and the switching valve V0, the main supply pipe 12 is connected to an ozone-water generator 5a through an ozone-water supply pipe 14. Note, the ozone-water supply pipe 14 includes a second valve V2. The ozone-water supplier 5 is formed by the ozone-water generator 5a, the second valve V2, the ozone-water supply pipe 14, the main supply pipe 12 and the supply nozzles 11. In this arrangement, by the ozone (O3) water produced by the ozone-water generator 5a and the pure water flowing in the main supply pipe 12, the supply nozzles 11 supply the ozone water of predetermined concentration e.g. less than 10 PPM into the processing bath 1. Here, the reason why the concentration of ozone water is established to be less than 10 PPM is because the concentration of ozone water more than 10 PPM might cause the resist on the wafers W to be dissolved in the ozone water. Note, if the concentration of ozone water is established within a range from 0.5 to 10 PPM, then it is possible to provide each surface of the wafers W with an oxidation film of film-thickness, which is necessary to realize hydrophilic surfaces of the wafers W, for example, a thickness from 6 to 10 Å.

Meanwhile, the drying chamber 2 is formed with a size allowing a plurality (e.g. fifty sheets) of wafers W to be accommodated therein. The drying chamber 2 is mainly formed by a container body 16a having a loading/unloading port 15 formed at a top end of the body 16a and a container cover 16b for closing the loading/unloading port 15. In this arrangement, the container cover 16b is formed to have, for example, a reverse U-shaped section and also adapted so as to move up and down by the elevating mechanism 8. The elevating mechanism 8 is connected to the CPU 10. On receipt of the control (operational) signals from the CPU 10, the elevating mechanism 8 is activated to open or close the container cover 16b. When the container cover 16b rises, the loading/unloading port 15 is opened to allow the wafers W to be loaded into the container body 16a. Due to the descent of the container cover 16b after the wafers W have been loaded and accommodated in the container body 16a, the loading/unloading port 15 is closed up. In this arrangement, a clearance between the container body 16a and the container cover 16b is sealed up by a lip-type O-ring 17a.

As shown in FIG. 1, the above wafer guide 7 is mainly formed by a guide part 7a and three parallel holding members 7b, 7c, 7d secured to the guide part 7a horizontally. The holding members 7b, 7c, 7d each has fifty grooves (not shown) formed at regular intervals to hold the lower peripheries of the wafers W. Thus, the wafer guide 7 is capable of holding fifty wafers W while they are arranged at regular intervals. The wafer guide 7 is provided, in succession with the guide part 7a, with a shaft 7e which slidably penetrates a through-hole 16c formed on the top of the container cover 16b. An expandable O-ring 17b is interposed between the through-hole 16c and the shaft 7e thereby to maintain a leak-tight condition established in the drying chamber 2. An elevating mechanism (not shown) for the wafer guide 7 is connected with the CPU 10 which generates control (operational) signals to operate the wafer guide 7.

The processing bath 1 and the drying chamber 2 are arranged side by side through a communication port 15a. In the communication port 15a, a shutter 9 as opening/closing means is arranged so as to open and close the port 15a. Owing to the provision of the shutter 9, the processing bath 1 and the drying chamber 2 can be insulated from each other. The shutter 9 has a drive part 9a connected to the CPU 10 which generates control (operational) signals to open or close the communication port 15a.

The essential part of the above dry-gas supplier 6 is formed by gas-supply nozzles 11A arranged on the top side in the drying chamber 2, a dry-gas (e.g. N2-gas) source 6a connected to the nozzles 11A through a gas supply pipe 18 and a third valve 3 interposed in the gas-supply pipe 18. In this arrangement, the gas-supply pipe 18 includes a temperature regulator 6b to produce hot N2-gas. The temperature regulator 6b and the third valve V3 are operated by the control (operational) signals from the CPU 10.

Note, the above chemical-liquid supplier 3, the rinsing-liquid supplier 4, the ozone-water supplier 5, the dry-gas supplier 6, the wafer guide 7, the container-cover elevating mechanism 8, the shutter 9, etc. are all controlled on the basis on memory/information programmed in the CPU 10 previously.

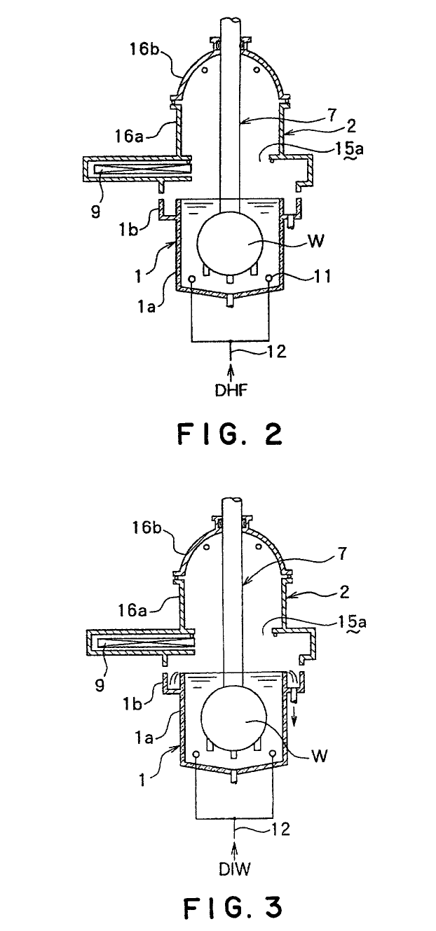

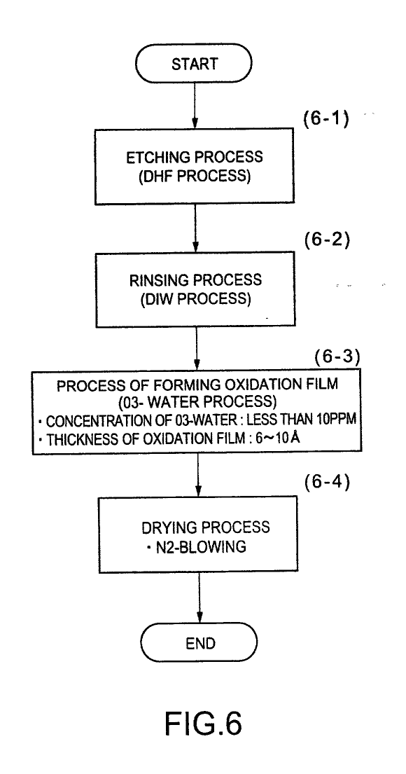

Next, the processing order of the wafers W in the processing apparatus will be described with reference to schematic sectional views of FIGS. 2 to 5 and a flow chart of FIG. 6.

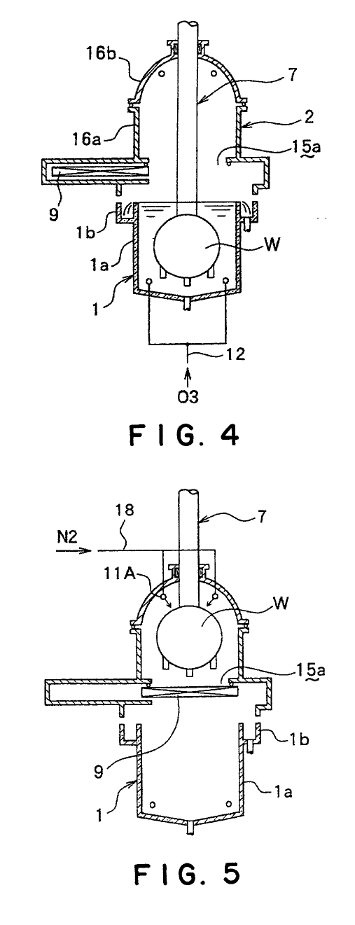

First, it is carried out to deliver plural wafers, for example, fifty wafers W, which have been transported by not-shown wafer transferring means, to the wafer guide 7 rising above the processing apparatus. Successively, after the wafer guide 7 has come down, the container cover 16b is closed to accommodate the wafers W in the processing bath 1. While accommodating the wafers W in the processing bath 1, it is first executed to drive the pump 3b and open the first valve V1. Simultaneously, the switching valve V0 is turned to the side of the chemical supply tank 3a, so that the chemical liquid (DHF) is supplied to the wafers W in the processing bath 1. Thus, the oxidation films on the wafers W are removed in the etching process using the liquid DHF [step 6-1 (see FIG. 2)]. Next, with the stop of the operation of the pump 3b, the switching valve V0 is turned to the side of the pure-water source 4a to supply the wafers W in the processing bath 1 with the rinsing liquid (DIW). Thus, the surfaces of the wafers W are cleaned while causing the liquid to overflow into the outer bath 1b [step 6-2 (see FIG. 3)]. After washing the wafers W, the second valve V2 is opened to let the ozone (O3) water produced by the ozone-water generator 5a to flow into the main supply pipe 12. Thus, it is performed to supply the ozone (O3) water of a predetermined concentration (e.g. less than 10 PPM) through the supply nozzles 11, so that the oxidation films (film thickness: 6-10 Å) are formed on the wafers W for their hydrophilicity with the overflow of the liquid into the outer bath 1b [step 6-3 (see FIG. 4)].

After completing the etching process to remove the oxidation films from the wafers W, the rinsing process to wash them and the hydrophilic process to form the oxidation films on the wafers W in the above way, the wafer guide 7 is elevated to move the wafers W into the drying chamber 2 above the processing bath 1. At this time, the shutter 9 is moved toward its closing position. Thus, the drying chamber 2 is insulated from the processing chamber 1 and further closed uptightly. In this state, the third valve V3 is opened and further, the temperature regulator 6b is operated to supply the drying chamber 2 with hot-N2 gas from the N2-gas source 6a, completing the drying process of the wafers W [step 6-4 (see FIG. 5)]. In this drying process, there is no fear of water-marks on the wafers W because of their hydrophilic surfaces.

After completing the drying process in the above way, the elevating mechanism 8 is operated to raise the container cover 16b for opening the loading/unloading port 15 of the container body 16a. Thereafter, the wafer guide 7 is elevated to unload the wafers W above the drying chamber 2. Then, the wafers W are delivered to the not-shown wafer transferring means for transporting them to the next processing part.

2nd. Embodiment

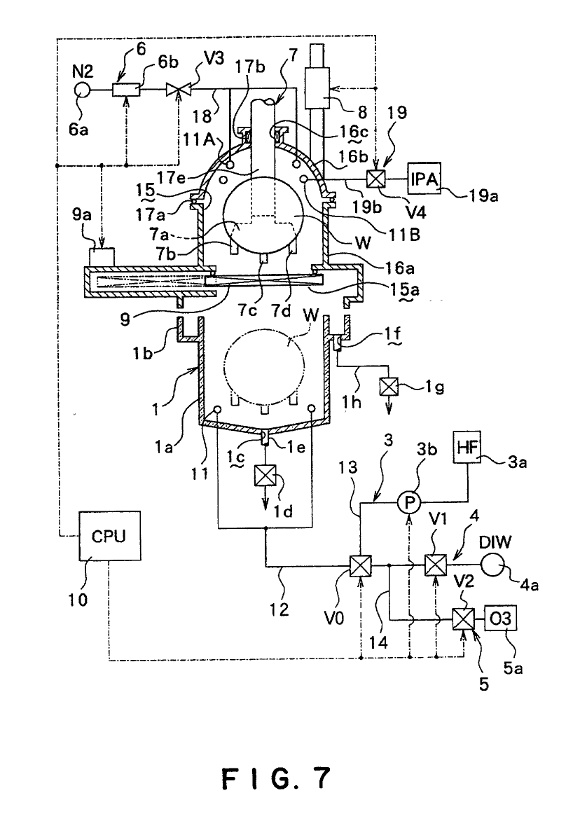

FIG. 7 is a schematic sectional view showing the second embodiment of the substrate surface processing apparatus of the present invention.

The second embodiment is directed to process the wafers W having resist-patterns formed thereon and also the wafers W with no resist-pattern effectively.

In addition to the elements of the processing apparatus of the first embodiment, the processing apparatus of the second embodiment includes supply nozzles 11B which supply the drying chamber 2 with drying solvent, for example, isopropyl alcohol (IPA) vapor or mixture gas consisting of IPA and gas, and an IPA source 19a which is connected to the IPA nozzles 11b through an IPA supply pipe 19b including a fourth valve V4. The IPA supply nozzles 11B, the supply source 19a for IPA vapor or gas containing IPA, the IPA supply pipe 19b and the fourth valve V4 constitute an IPA supplier 19. The fourth valve V4 is operated so as to open or close by control (operative) signals from the CPU 10.

As to the second embodiment of the invention, other parts are similar to those of the first embodiment. Therefore, the identical parts are indicated with the same reference numerals in the first embodiment respectively and explanations of the parts will be eliminated.

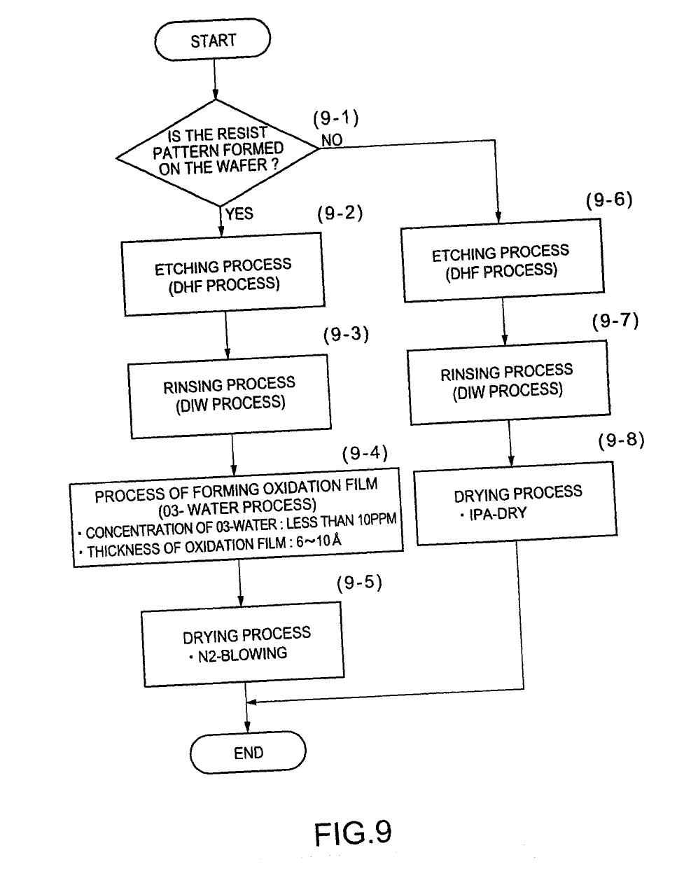

Next, the processing order in the second embodiment will be described with reference to schematic sectional views of FIGS. 2-5 and 8 and a flow chart of FIG. 9.

According to the second embodiment, it is judged whether or not the wafers W to be processed have resist-patterns formed thereon (step 9-1). When the resist patterns are formed on the wafers W, they are processed as similar to the first embodiment. That is, while accommodating the wafers W in the processing bath 1, it is first executed to drive the pump 3b and open the first valve V1. Simultaneously, the switching valve V0 is turned to the side of the chemical supply tank 3a, so that the oxidation films on the wafers W are removed in the etching process using the liquid DHF [step 9-2 (see FIG. 2)]. Next, with the stop of the operation of the pump 3b, the switching valve V0 is turned to only the side of the pure-water source 4a to supply the wafers W in the processing bath 1 with the rinsing liquid (DIW). Thus, the surfaces of the wafers W are cleaned while causing the liquid to overflow into the outer bath 1b [step 9-3 (see FIG. 3)]. After washing the wafers W, the second valve V2 is opened to let the ozone (O3) water produced by the ozone-water generator 5a to flow into the main supply pipe 12. Thus, it is performed to supply the ozone (O3) water of a predetermined concentration (e.g. less than 10 PPM) through the supply nozzles 11, so that the oxidation films (film thickness: 6-10 Å) are formed on the wafers W for their hydrophilicity with the overflow of the liquid into the outer bath 1b [step 9-4 (see FIG. 4)].

After completing the etching process to remove the oxidation films from the wafers W, the rinsing process to wash them and the hydrophilic process to form the oxidation films on the wafers W in the above way, the wafers W are moved into the drying chamber 2 by the wafer guide 7. In this state, the third valve V3 is opened and further, the temperature regulator 6b is operated to supply the drying chamber 2 with hot-N2 gas from the N2-gas source 6a, completing the drying process of the wafers W [step 9-5 (see FIG. 5)]. In this drying process, there is no fear of water-marks on the wafers W because of their hydrophilic surfaces.

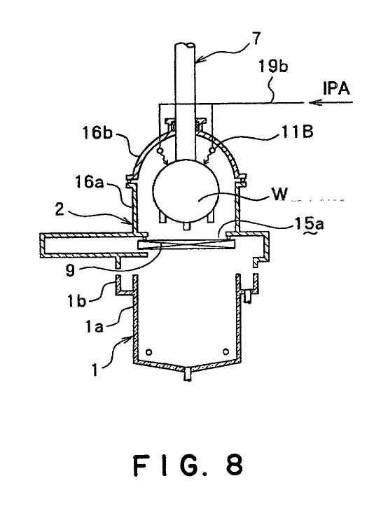

On the other hand, as to the wafers W having no resist pattern formed thereon, the rinsing process [step 9-7 (see FIG. 3)] is performed after completing the etching process [step 9-6 (see FIG. 2)], as similar to the case of the wafers W having the resist patterns formed thereon. Then, after completing the rinsing process, the wafers W are moved into the drying chamber 2 by the wafer guide 7. In this state, the fourth valve V4 is opened to supply the drying chamber 2 with IPA vapor from the IPA supply source 19a, completing the drying process of the wafers W [step 9-8 (see FIG. 8)]. According to this drying process, as the wafers W are dried while the moisture are replaced by IPA-vapor, there is no fear of water-marks on the wafers W.

3rd. Embodiment

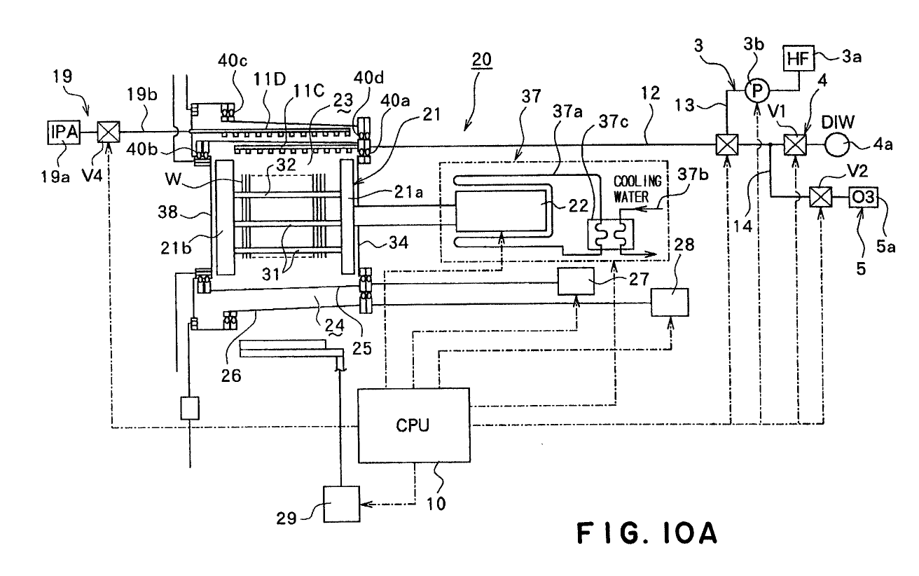

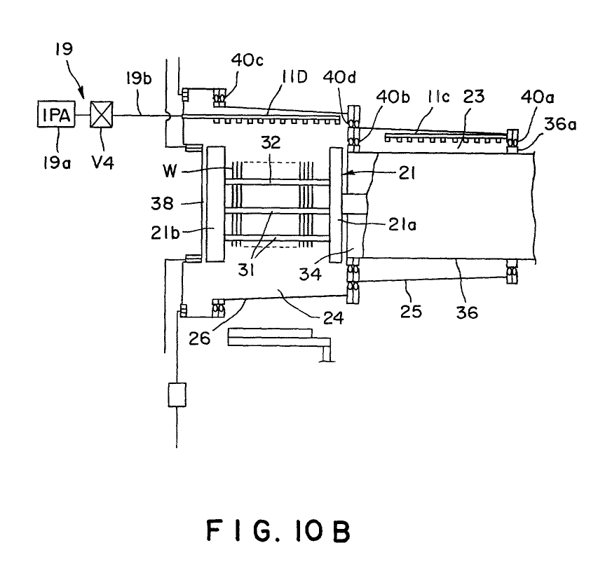

FIG. 10A is a schematic sectional view showing the substrate-surface processing apparatus in accordance with the third embodiment of the present invention. The third embodiment is directed to perform the etching process of the wafers W, the rinsing process, the hydrophilic process and the drying process while changing two chambers to each other.

As shown in FIG. 10A, a processing apparatus 20 of the third embodiment includes a rotary holder for holding the wafers W, such as a rotor 21, a driver for rotating the rotor 21 about a horizontal shaft as a center, such as a motor 22, inner and outer chambers 23, 24 both defining two chambers as containers surrounding the wafers W held by the rotor 21, moving means (e.g. first and second cylinders 27, 28) for moving an inner cylinder 25 forming the inner chamber 23 and an outer cylinder 26 forming the outer chamber 24 to a position to surround the wafers W and a stand-by position apart from the position to surround the wafers W, and a wafer-delivery hand 29 which delivers the wafers W to the rotor 21 and also receives them from the rotor 21. Further, in the inner chamber 23, there are arranged first supply nozzles 11C which are connected to the rinsing-liquid supplier 4, the chemical-liquid supplier 3 and the ozone-water supplier 5 all formed in the same manner as the first embodiment. Also, in the outer chamber 24, there are arranged second supply nozzles 11D to which the IPA supply source 19a is connected through the IPA supply pipe 19b including the fourth valve V4, as similar to the second embodiment mentioned above.

In the processing apparatus constructed above, the motor 22, the first, second and the fourth valves V1, V2, V4 of the respective suppliers 3, 4, 5, 6, 19, the switching valve V0, the wafer-delivery hand 29, etc. are controlled on the basis of control (operational) signals from the CPU 10.

Note, since it is feared that the motor 22 is overheated, it is provided with a cooler unit 37 which restricts the overheating of the motor 22. As shown in FIG. 10A, this cooler unit 37 is formed by a circulation-type cooling pipe 37a arranged around the motor 22 and a heat exchanger 37c containing a part of the cooling pipe 37a and a part of cooling-water supply pipe 37b to cool a coolant liquid packed in the cooling pipe 37a. In this case, employed as the coolant liquid is an electrical insulative and heat-conductive liquid that would not cause a leak of electricity in the motor 22 if the liquid leaks out, for example, ethylene glycol. Further, for the operation based on signals detected by a not-shown temperature sensor, the cooler unit 37 is controlled by the CPU 10.

On the other hand, the processing chamber, for example, the inner chamber 23 is formed by a first fixed wall 34, a second fixed wall 38 facing onto the first fixed wall 34 and an inner cylinder 25 engaging with the first fixed wall 34 and the second fixed wall 38 through first and second sealing members 40a, 40b, respectively. That is, when the inner cylinder 25 is moved to a position to encircle the rotor 21 and the wafers W due to the expansion of the first cylinder 27 as the moving means, the inner chamber 23 is defined while the cylinder 25 is sealed to the first fixed wall 34 through the first sealing member 40a and also sealed to the second fixed wall 38 through the second sealing member 40b. While, due to the shrinkage of the first cylinder 27, the inner cylinder 25 is moved to a position (stand-by position) in the circumference of a fixed cylinder 36, as shown in FIG. 10B. Then, an opening at the leading end of the fixed cylinder 36 is sealed to the first fixed wall 34 through the second sealing member 40b, while the base end of the inner cylinder 25 is sealed to a flange part 36a formed around the intermediate part of the fixed cylinder 36 through the first sealing member 40a, preventing a chemical atmosphere remaining in the inner chamber 23 from leaking outside.

The outer chamber 24 is formed by the first fixed wall 34 interposing the second sealing member 40b against the inner cylinder 25 in the stand-by position, the second fixed wall 38 and the outer cylinder 26 engaging with the second fixed wall 38 through a third sealing member 40c and also engaging with the inner cylinder 25 through a fourth sealing member 40d. That is, when the outer cylinder 26 is moved to a position to encircle the rotor 21 and the wafers W due to the expansion of the second cylinder 28 as the moving means, the outer chamber 24 is defined while the cylinder 26 is sealed to the second fixed wall 38 through the third sealing member 40c and also sealed to the leading end of the inner cylinder 25 through the fourth sealing member 40d positioned inside the base end of the outer cylinder 26. While, due to the shrinkage of the second cylinder 28, the outer cylinder 26 can be moved to a position (stand-by position) in the circumference of the fixed cylinder 36. In this state, the fourth sealing member 40d is interposed between the base ends of the outer cylinder 26 and the inner cylinder 25, effecting the sealing function. Thus, since the inside atmosphere of the inner chamber 23 and the inside atmosphere of the outer chamber 24 are insulated from each other in a leak-tight manner, it is possible to prevent the atmospheres in the chambers 23, 24 from being mixed with each other, preventing an occurrence of cross-contamination due to the reaction between different processing fluids.

The above-constructed inner and outer cylinders 25, 26 are together tapered so as to spread toward one end of the apparatus gradually. Additionally, the cylinders 25, 26 are attached to the apparatus so as to be slidable along a plurality (e.g. three) of parallel guide rails (not shown) installed on the first fixed wall 34, the second fixed wall 38 and an apparatus sidewall (not shown) all opposing each other on the same horizontal line. Thus, due to the expansion and shrinkage of the first and second cylinders 27, 28, the inner and outer cylinders 25, 26 are adapted so as to project from each other and also overlap each other, coaxially. In this way, owing to the tapered formation of the inner and outer cylinders 25, 26 both spreading toward one end of the apparatus gradually, an air current generated by the rotation of the rotor 21 in the inner cylinder 25 or the outer cylinder 26 at processing can flow toward the expanded side of the cylinder in a spiral manner, allowing an interior chemical liquid to be discharged to the expanded side with ease. Additionally, owing to the structure where the inner cylinder 25 and the outer cylinder 26 can overlap with each other coaxially, it is possible to reduce an installation space for the inner and outer cylinders 25, 26 and the inner and outer chambers 23, 24, allowing the apparatus to be small-sized.

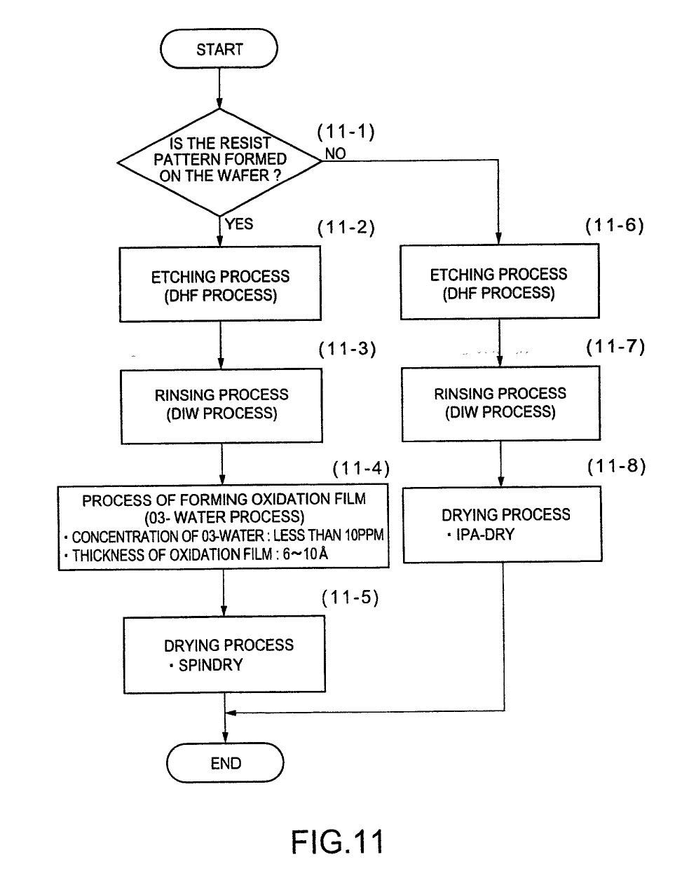

Next, the processing order of the third embodiment will be described with reference to a flow chart of FIG. 11.

According to the third embodiment, which is similar to the second embodiment, it is judged whether or not the wafers W to be processed have resist-patterns formed thereon (step 11-1). When the resist patterns are formed on the wafers W, they are processed as similar to the first and second embodiments. That is, while accommodating the wafers W in the inner chamber 23, it is first executed to drive the pump 3b and open the first valve V1. Simultaneously, the switching valve V0 is turned to the side of the chemical supply tank 3a and the liquid DHF is supplied to the wafers W rotating together with the rotor 21, thereby removing the oxidation films on the wafers W by the etching process using the liquid DHF (step 11-2). Next, with the stop of the operation of the pump 3b, the switching valve V0 is turned to only the side of the pure-water source 4a to supply the rinsing liquid (DIW) to the wafers W rotating together with the rotor 21 for cleaning the surfaces of the wafers W (step 11-3). After washing the wafers W, the second valve V2 is opened to let the ozone (O3) water produced by the ozone-water generator 5a to flow into the main supply pipe 12. Thus, it is performed to supply the ozone (O3) water of a predetermined concentration (e.g. less than 10 PPM) through the supply nozzles 11, so that the oxidation films (film thickness: 6-10 Å) are formed on the wafers W for their hydrophilicity (step 11-4).

After completing the etching process to remove the oxidation films from the wafers W, the rinsing process to wash them and the hydrophilic process to form the oxidation films on the wafers W in the above way, it is executed to position the wafers W in the outer chamber 24 with the retreat of the inner chamber 23. In this state, the rotor 21 is rotated at a high speed to remove moisture adhering to the surfaces of the wafers W by the rotor's centrifugal force, completing the drying process of the wafers W (step 11-5). In this drying process, there is no fear of water-marks on the wafers W because of their hydrophilic surfaces.

On the other hand, as to the wafers W having no resist pattern formed thereon, the rinsing process (step 11-7) is performed after completing the etching process (step 11-6), as similar to the case of the wafers W having the resist patterns formed thereon. Then, after completing the rinsing process, it is executed to position the wafers W in the outer chamber 24 with the retreat of the inner chamber 23. In this state, the fourth valve V4 is opened to supply the outer chamber 24 (drying chamber) with IPA vapor from the IPA supply source 19a, completing the drying process of the wafers W (step 11-8). According to this drying process, as the wafers W are dried while the moisture are replaced by IPA-vapor, there is no fear of water-marks on the wafers W. Then, it is also possible to rotate the rotor 21.

In the third embodiment, the wafers W is processed in the inner chamber 23, while the drying operation is performed in the outer chamber 24 only. Nevertheless, the present method is not always limited to such a processing form. For example, the chemical process may be performed in the inner chamber 23 while carrying out both rinsing and drying processes in the outer chamber 24.

Other Embodiments

Although the above embodiments are related to the arrangements to position two processing chambers in succession and form these chambers into one body, the processing chamber and the drying chamber may be formed independently of each other so as to perform the etching, rinsing and hydrophilic process and the drying process in different processing sections.

Alternatively, both of the processing and drying may be executed in the same chamber. That is, it is also possible to employ one method that the etching, rinsing and hydrophilic process are performed while accommodating the wafers W in the processing bath 1 in the first and second embodiments and subsequently, the wafers W are dried by the supply of dry gas (N2-gas) after or while draining the ozone (O3)-water or the rinsing liquid (DIW).

Again, the wafers W are processed and dried in two chambers (i.e. the inner chamber 23 and the outer chamber 24) in the third embodiment. Nevertheless, if only providing one processing chamber with a supply port for liquid and also a supply port for IPA-vapor or mixed gas of IPA and gas, then it is possible to perform all steps consisting of the above process and sequent drying process in the single processing chamber.

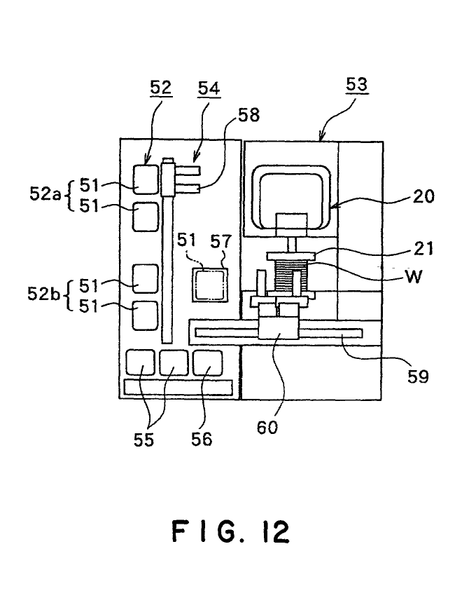

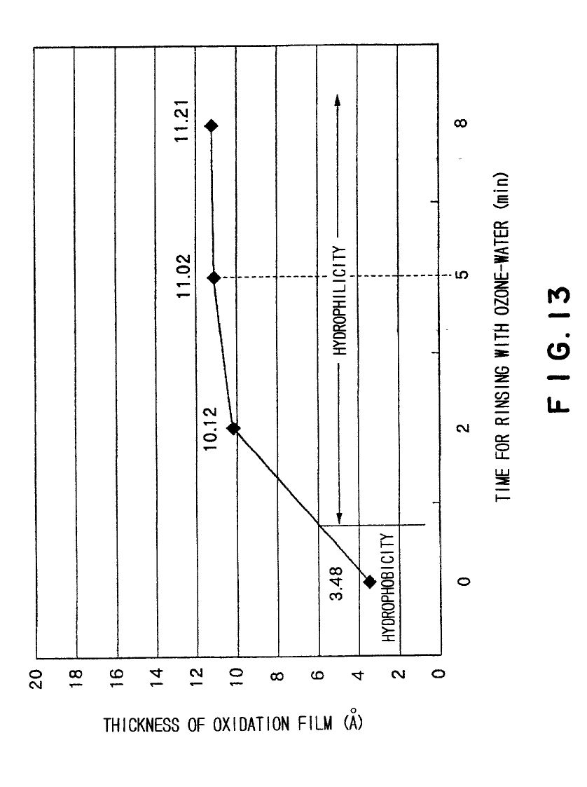

Although the substrate-surface processing apparatus is solely employed in common with the above-mentioned embodiments, it is preferable to operate the same apparatus in a cleaning/drying system shown in FIG. 12.

The above cleaning/drying system is mainly formed by a loading/unloading part 52 for loading or unloading containers, for example, carriers 51 for each accommodating a plurality (e.g. fifty) of wafers W, a processing part 53 to perform the etching, rinsing and hydrophilic process and the drying process against the wafers W and an interface part 54 arranged between the loading/unloading part 52 and the processing part 53 to deliver the wafers W therebetween, adjust the position of the wafers W and further change their postures. Note, beside the loading/unloading part 52 and also the interface part 54, there are arranged carrier stocks 55 to accommodate the empty carriers 51 temporarily and also a carrier cleaner 56 for cleaning the carriers 51.

The above loading/unloading part 52 is arranged on one lateral side of the cleaning/drying apparatus and juxtaposes a carrier-loading part 52a and a carrier-unloading part 52b.

In the above interface part 54, there is arranged a carrier mount 57. Further, between the carrier mount 57 and the loading/unloading part 52, there is arranged a carrier conveyer 58 which transfers the carrier 51 from the carrier-loading part 52a onto the carrier mount 57 or the carrier stock 55 and also transfers the carrier 71 on the carrier mount 57 to the carrier-unloading part 52b or the carrier stock 55. The interface part 54 includes a conveyer path 59 succeeding the processing part 53. In the conveyer path 59, a wafer conveyer, for example, a wafer-transfer chuck 60 is arranged so as to be movable on the path 59. This wafer-transfer chuck 60 is constructed so as to receive the non-processed wafers W from the carrier 51 on the carrier mount 7, continuously transfer the wafers W to the processing part 53 and also load the processed wafers W, which have been processed in the processing part 53, into the carrier 51.

Experiments

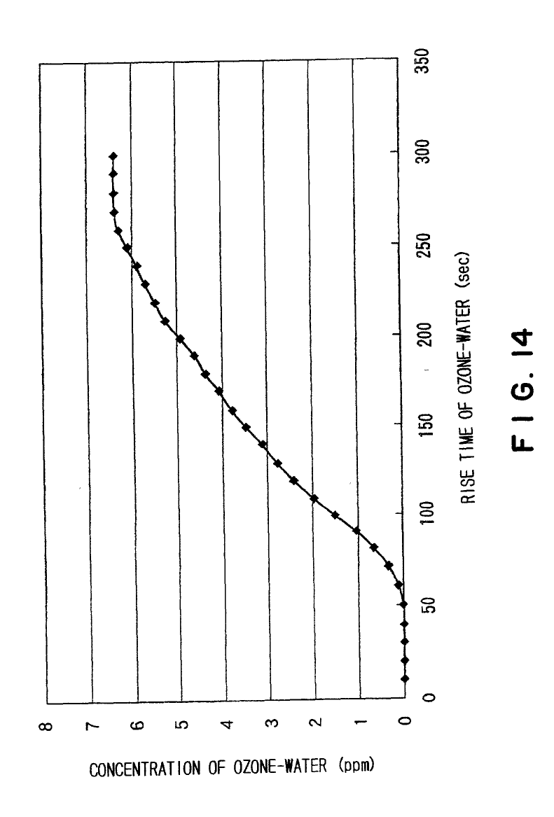

In order to establish the concentration of ozone-water accomplishing the oxidation films each having a film-thickness from 6 to 10 Å required to make the surfaces of the wafers W hydrophilic, we examined a relationship between oxidation film and rinsing time with the ozone-water and also a relationship between concentration and rise time of the ozone-water. Consequently, the results are shown in FIGS. 13 and 14.

As a result of the above experiments, it is found that the rinsing operation for approx. 1 to 2 min. using the ozone-water is necessary to form the oxidation films each having the film-thickness from 6 to 10 Å in order to make the surfaces of the wafers W hydrophilic, as shown in FIG. 13. Additionally, as shown in FIG. 14, it is found that the concentration of ozone-water when the rise time of ozone-water ranges from approx. 1 to 2 min. (60 to 120 sec.) ranges from 0.5 to 3 PPM. Therefore, it is preferable that the minimum in the concentration of ozone-water has only the order of 0.5 PPM. If only the concentration of ozone-water ranges from 0.5 to 10 PPM, then it is possible to make the surfaces of the wafers W hydrophilic without dissolving the resists formed thereon.

Note, the oxidation film with the order of 10 Å is required to attain a uniform film-thickness. The concentration of ozone-water is desirable to be from 3 to 10 PPM to stabilize the hydrophilicity of the surfaces of the wafers W.

For comparing the processing efficiency of the conventional processing method with that of the present method, we carried out tests under the following conditions:

Conditions

1) Comparison 1:

Etching process (DHF)

→Rinsing process (DI rinsing) {900 sec.}

→Drying process with IPA vapor/N2 blow

2) Comparison 2:

Etching process (DHF)

→Rinsing process (DI rinsing) {900 sec.}

→Drying process with N2 blow (not using IPA)

3) Embodiment of Invention:

Etching process (DHF)

→Rinsing process (DI rinsing)/ O3-water rinsing {900 sec. in total}

→Drying process with N2 blow

Here, test conditions are as follows.

Etching process: 160 sec. (etching=50 Å), Concentration 200:1

DI rinsing: 25 liter/min. 900 sec.

O3-water rinsing: 12 liter/min. 300 sec. Concentration 5 PPM,

Wafers: 8 inches, 50 pieces

Drying process: IPA-vapor=40 sec./N2=300 sec.

N2-drying=480 sec.

As a result of examining the number of water-marks produced on the wafer W under the above conditions, the water-marks more than 5,000 in number were detected in the comparison 2. To the contrary, the water-marks less than 10 were detected in the comparison 1 and the embodiment of the invention. Consequently, it is found that the processing method of the invention can restrict the generation of water-marks without collapsing the resist pattern.

What is claimed is:

1. A method of processing a surface of a substrate to be processed, the method comprising:
an etching process to supply the substrate having a resist pattern formed thereon with a chemical liquid thereby to remove an oxidation film on the surface of the substrate therefrom;
a rinsing process to supply the substrate with a rinsing liquid thereby to wash the surface of the substrate;
a hydrophilic process to supply the substrate with an ozone water thereby to form an oxidation film on the surface of the substrate for providing hydrophilicity therefor; and
a drying process to eliminate moisture adhering to the surface of the substrate.

2. A method as claimed in claim 1, wherein the drying process is accomplished by supplying dry gas to the substrate to be processed.

3. A method as claimed in claim 1, wherein the drying process is accomplished by rotating the substrate to be processed.

4. A method as claimed in claim 1, wherein the ozone water in the hydrophilic process has a concentration ranging from 0.5 to 10 PPM.

5. A substrate-surface processing method of sorting out a substrate having a resist pattern formed thereon from another substrate having no resist pattern formed thereon and further applying different processes to the substrates selectively, the method comprising, for the substrate having the resist pattern formed thereon:
an etching process to supply the substrate with a chemical liquid thereby to remove an oxidation film on the surface of the substrate therefrom;
a rinsing process to supply the substrate with a rinsing liquid thereby to wash the surface of the substrate;
a hydrophilic process to supply the substrate with an ozone water thereby to form an oxidation film on the surface of the substrate for hydrophilicity thereof; and
a drying process to eliminate moisture adhering to the surface of the substrate;
the method comprising, for the substrate having no resist pattern formed thereon:
an etching process to supply the substrate having no resist pattern formed thereon with a chemical liquid thereby to remove an oxidation film on the surface of the substrate therefrom;
a rinsing process to supply the substrate with a rinsing liquid thereby to wash the surface of the substrate; and
a drying process to supply the substrate with a dry solvent thereby to eliminate moisture adhering to the surface of the substrate.

6. A substrate-surface processing method as claimed in claim 5, wherein the drying process for the substrate having the resist pattern formed thereon is accomplished by supplying dry gas to the substrate to be processed.

7. A substrate-surface processing method as claimed in claim 5, wherein the drying process for the substrate having the resist pattern formed thereon is accomplished by rotating the substrate to be processed.

8. A substrate-surface processing apparatus for processing a surface of a substrate to be processed, the apparatus comprising:
a processing container for accommodating the substrate therein;
a chemical-liquid supply system for supplying the substrate in the processing container with a chemical liquid for removing an oxidation film formed on the substrate;
a rinsing-liquid supply system for supplying the substrate in the processing container with a rinsing liquid for washing;
an ozone-water supply system for supplying the substrate in the processing container with an ozone water;
a substrate drying system for drying the substrate in the processing container;
a dry-solvent supply system for supplying the substrate in the processing container with a dry solvent; and
a controller for generating operative signals to drive both of the ozone-water supply system and the substrate drying system when the substrate having a resist pattern formed thereon is accommodated in the processing container, the controller also generating an operative signal to drive the dry-solvent supply system in place of the ozone-water supply system and the substrate drying system when the substrate having no resist pattern formed thereon is accommodated in the processing container.

9. A substrate-surface processing apparatus as claimed in claim 8, wherein the substrate drying system is a dry-gas supply system for supplying dry gas into the processing container.

10. A substrate-surface processing apparatus as claimed in claim 9, wherein the rinsing-liquid supply system has a supply pipe which connects a rinsing-liquid source for the rinsing liquid for washing with the processing container;
the chemical-liquid supply system has a chemical-liquid source for reserving the chemical liquid for removing the oxidation film and a chemical-liquid pipe connecting the chemical-liquid source with the supply pipe; and
the ozone-water supply system has an ozone-water source and an ozone-water pipe connecting the ozone-water source with the supply pipe.

11. A substrate-surface processing apparatus as claimed in claim 8, wherein the substrate drying system is a rotary drying system which rotates the substrate.

12. A substrate-surface processing apparatus as claimed in claim 11, wherein the rinsing-liquid supply system has a supply pipe which connects a rinsing-liquid source for the rinsing liquid for washing with the processing container;
the chemical-liquid supply system has a chemical-liquid source for reserving the chemical liquid for removing the oxidation film and a chemical-liquid pipe connecting the chemical-liquid source with the supply pipe; and
the ozone-water supply system has an ozone-water source and an ozone-water pipe connecting the ozone-water source with the supply pipe.

13. A substrate-surface processing apparatus as claimed in claim 9, wherein the processing container contains a liquid-process container for carrying out a liquid processing inside thereof and a dry-process container for carrying out a drying process inside thereof.

14. A substrate-surface processing apparatus as claimed in claim 13, wherein the dry-process container is arranged above the liquid-process container; and
the liquid-process container has a liquid-process chamber connected with a dry-process chamber in the dry-process container through a communication port arranged between the liquid-process container and the dry-process container.

15. A substrate-surface processing apparatus as claimed in claim 11, wherein the processing container contains a liquid-process container for carrying out a liquid process inside thereof and a dry-process container for carrying out a drying process inside thereof.

16. A substrate-surface processing apparatus as claimed in claim 15, wherein the liquid-process container is arranged so as to be insertable into and withdrawable from the dry-process container;
at the liquid process, the liquid-process container performs the liquid process while accommodating the substrate therein; and
at the drying processing, the liquid-process container withdraws from a position to accommodate the substrate therein and the dry-process container performs the drying process while accommodating the substrate therein.
